(19) United States
(12) Patent Application Publication
(10) Pub. No.: US 2008/0208494 A1
(43) Pub. Date: Aug. 28, 2008

(54) Method and Device for Determining the Charge and/or Aging State of an Energy Store

(76) Inventors: Matthias Holz, Lehre (DE); Michael Zillmer, Sickte (DE); Ekkehard Pott, Gifhorn (DE); David Prochazka, Libosovice (CZ)

Correspondence Address: KENYON & KENYON LLP, ONE BROADWAY, NEW YORK, NY, 10004, US

(21) Appl. No.: 11/916,951

(22) PCT Filed: Mar. 29, 2006
(86) PCT No.: PCT/EP2006/002828

§ 371 Date: Jan. 7, 2008

(30) Foreign Application Priority Data
Jun. 7, 2005 (DE) 10 2005 026 077.2

(51) Int. Cl. G01R 31/36

(52) U.S. Cl. 702/64

(57) ABSTRACT

In a method and a device for determining a charge/aging state of an energy store, the charge/aging state is able to be determined by a control unit on the basis of an open terminal voltage of the energy store, able to be measured with the aid of a voltage-measuring sensor, in a load-free state. It is provided that the control unit initiates a measurement of a first open terminal voltage at a first instant following the occurrence of the load-free state of the energy store and, based on the measured first open terminal voltage, the control unit, with the aid of a prediction model, specifies a future instant for at least one additional measurement of the open terminal voltage, and at least one additional open terminal voltage is measured at the future instant, and the charge/aging state of the energy store is determined with the aid of the at least one additional open terminal voltage.

### FIELD OF THE INVENTION

The present invention relates to a method and to a device for determining the charge and/or aging state of an energy source.

### BACKGROUND INFORMATION

When using electrical energy stores it is important to have knowledge of their charge and aging state. Electrical energy stores may be electrochemical energy stores or capacitance stores, for example. Accurate knowledge of the charge state (SOC—state of charge) or the aging state (SOH—state of health) is important in connection with, for instance, the operation of an energy store in a hybrid vehicle that includes a combustion engine and at least one electromachine as alternative or cumulative drive machines. In particular for an energy-efficient driving management will it be necessary to know the charge or aging state of the energy store as accurately as possible.

Conventional methods for determining the charge state or the energy content of an energy store are based on a current or voltage measurement at the battery terminals. If a current is measured, the portion of the drained or supplied charge relative to the nominal capacitance is determined by integrating the battery current over the time. If the pure current measurement is additionally linked to a voltage measurement at the battery terminals, then it is possible to consider a dependency of the energy content from discharge capacity P in addition. Both methods allow the consideration of additional effects such as the age of the energy store, a self-discharge of the energy store, a temperature of the energy store, etc. via corresponding calculation methods.

However, the charge quantity extractable from an energy store, in particular an electrochemical energy store such as a battery, has a marked dependency on the discharging current. For instance, in most batteries the extractable capacitance decreases as the discharging current rises (this is generally referred to as Peukert behavior). Furthermore, as the discharge depth increases, the terminal voltage of the battery decreases. The voltage drop at the inner resistor of the battery increases as a function of the discharging current from the battery. This further reduces the terminal voltage and thus leads to an imprecise determination of the energy content. Since only the capacitance but not the voltage characteristic's dependency on various influences is taken into account, a determination of the energy content of an electrical energy store therefore includes systematic errors.

Conventionally, the energy content is determined during normal vehicle operation by a current or charge integration (Ah integration) and is corrected with the aid of an additional measurement of the open terminal voltage of the energy store in the quiescent state of the energy store, the system being switched off, for example. A measurement of the terminal voltage in a load-free state of the electrical energy store is referred to as measurement of an open circuit voltage (OCV). Using a continuous measurement of the open circuit voltage while the vehicle is at a standstill or deactivated consequently provides an opportunity for an adaptation of influences such as a self-discharge or a temperature of the energy store in time-discrete steps. This retroactively compensates for the error of the current integration during vehicle operation.

However, the open circuit voltage of an energy store in the load-free state is not constant. In a load-free state, for example, the terminal voltage usually rises immediately after a current circuit is opened, due to internal compensation processes, if energy was withdrawn from the energy store when the current circuit was closed. Furthermore, external marginal conditions such as a temperature of the energy store, an age of the energy store, etc. influence the response of the energy store in the load-free state.

An unambiguous relation between the load/aging state (SOC/SOH) for an open terminal voltage exists only if the electrical energy store is in the quiescent state. An electrochemical energy store attains the quiescent state when a chemical equilibrium has come about under normal conditions of the environmental variables. It is therefore not sufficient to measure an open terminal voltage immediately after a discharge or charge process of the energy store.

Certain conventional methods address this technical problem. German Published Patent Application No. 102 08 652 describes a method in which at least two pairs of measured values for voltage and current are acquired. The acquired pairs of measured values for current and voltage are corrected to an energy store that is in a steady-state condition, taking a battery equivalent circuit into account. The corrected pairs of measured values are interpolated, and an open-circuit voltage value is determined in this manner at a current value of 0. On the basis of this determined open-circuit voltage value, the charge state is ascertained with the aid of a previously determined relationship between the open circuit voltage and the charge state.

PCT International Published Patent Application No. WO 02/091007 describes a method for determining a charge state of a battery by measuring an open terminal voltage. First, an open terminal voltage of the battery is measured for various charge states, in the quiescent state in each case, and a relationship between the open terminal voltage in the quiescent state and the charge state is produced in this manner. In order to determine the relationship between the open terminal voltage in the energy store's quiescent state and the individual charge state, the battery is charged and discharged in a stepwise manner. After each charge and discharge step the voltage characteristic as well as a temperature response is recorded at time intervals against the time until the open-circuit voltage is attained. Based on these data, i.e., the open-circuit voltage, the change in the open terminal voltage, and the temperature of the battery, relaxation curves for the open terminal voltage are determined. These determined curves and the determined relation between the open terminal voltage in the quiescent state and the charge state of the battery are utilized to determine the open terminal voltage in the quiescent state and, therefrom, the particular charge state of the energy store, using measurements carried out within a brief time interval (100 to 500 seconds) after a discharge or charge operation.

German Published Patent Application No. 101 28 033 describes a method for predicting the equilibrated open-circuit voltage of an electrochemical energy store by measuring the voltage-setting response in a load-free period, the method utilizing a formula-type relationship between the equilibrated open-circuit voltage and the decaying voltage. This is dependent on two chronologically separate measured values of the terminal voltage in the load-free period and a temperature of the energy store, as well as on a plurality of constants to be determined experimentally.

However, these conventional measuring methods still exhibit considerable uncertainty with regard to the actual open terminal voltage in the quiescent state. In conventional devices which utilize energy stores, the open terminal voltage is therefore determined at time intervals during a load-free state in order to allow an accurate determination of the particular open-circuit voltage and the charge state or aging state of the energy store. However, in the case of longer idle phases or under disadvantageous initial conditions such as with an energy absorption at high currents and a high temperature of the energy store, large numbers of measurements are carried out that do not supply any meaningful results. These measurements themselves consume electrical energy, so that an improved method and an improved device are required to determine the charge and/or the aging state of an energy storage for an energy-efficient energy management.

### SUMMARY

Example embodiments of the present invention provide a method and a device for determining a charge/aging state of an energy store in a simple and reliable manner, without the need to carry out a multitude of unnecessary measurements.

To this end, a first open terminal voltage is measured at a first instant and, using a prediction model, a future instant is specified for at least one further measurement of the open terminal voltage based on the measured first open terminal voltage, and at least one additional open terminal voltage is measured at the future instant, and the charge/aging state of the energy store is determined on the basis of the at least one additional open terminal voltage. This avoids unnecessary measurements while the energy store is at rest in its quiescent state. This also avoids additional measurements that are carried out in certain conventional methods and devices once the energy store has attained its quiescent state. The measuring of an open terminal voltage is understood as the measurement of the terminal voltage of an energy store in a load-free state, i.e., with an open current circuit, which otherwise is provided for energy absorption/energy supply.

The future instant may be specified such that a quiescent state of the energy store is predicted for a future instant, utilizing the prediction model. In this example embodiment, it is ensured that the at least one additional measurement of the open terminal voltage is carried out at the future instant when the energy store is in its quiescent state, so that a reliable conclusion with regard to the charge or aging state of the energy store is possible.

To increase the reliability of the conclusion for the at least one additional measurement, an example embodiment provides that additional open terminal voltages are measured at the future instant. In this context, it may be provided that the additional open terminal voltages and the at least one additional terminal voltage are averaged and that this averaged value is used to determine the charge or aging state of the energy store.

The at least one additional open terminal voltage may be compared to an open terminal voltage at the future instant predicted on the basis of the prediction model. If the at least one additional open terminal voltage deviates from the predicted open terminal voltage by more than a specified tolerance, then the prediction model will be adapted. This makes it possible to consider, for example, production variances that occur in the production of the energy stores. The method is therefore self-learning and, within certain limits, is able to adapt to slightly different energy stores. In addition, this example embodiment is able to take change processes into account, which occur due to aging of the energy store, for instance.

Additional physical and/or statistical variables may be measured or recorded and taken into consideration in the prediction model, the physical variables including, in particular, an energy store temperature and/or an ambient temperature, and/or a charge/discharge current, and/or a charge/discharge capacity prior to the occurrence of the load-free state, and the statistical variables including, in particular, a time of day and/or an indicated season and/or information about a driving behavior. The prediction model may be refined considerably with the aid of these physical and/or statistical variables. For example, the temperature of the energy store is able to be taken into account. If an ambient temperature or, for instance, a temperature of an engine block in whose vicinity the energy store is installed, is also taken into account, then a temperature characteristic of the energy store is able to be incorporated into the prediction model as well. A driving behavior or an indicated time of day and season may affect a determination of the future instant. For example, if a company vehicle is never used on weekends, then this may be taken into account in determining the future instant when the vehicle is parked on the company's property on Friday evenings. In this manner, it is possible to specify the future instant as the early morning hours of the following day, for example, when it may be assumed that the energy store will be in a quiescent state under normal conditions due to the ambient temperature. If the method is utilized in connection with an energy store installed in a vehicle used as taxi, for example, then the load-free states of the energy store are usually shorter than one day. If the method is used with an energy store that is installed in a hybrid vehicle and to which a capacitor store is connected in parallel, which takes over a large share—such as more than 80% or more than 90%—of the energy output and energy absorption during the vehicle operation, then the average duration of a load-free state is heavily dependent upon the driving behavior of the vehicle driver.

The prediction model may include mathematically evaluable equations. For instance, a prediction model may be a physical model, which models both the energy store and its environment such as the temperature characteristic.

The prediction model may include reference tables, which are stored in a memory. In this example embodiment, the prediction model may be based—either completely or partly—on empirically determined variables.

The physical and/or statistical variables taken into account in the prediction model may be acquired either by measuring sensors of its own or adopted from other components of a vehicle in which the energy store is installed. The ambient temperature, for example, may be obtained from a climate-control device of the vehicle. As an alternative or in addition, it may be provided that the temperature sensors are installed on or in the energy store, in the environment of the energy store, or at heat sources such as an engine, in the proximity of the energy store.

Additional features of the device according to example embodiments of the present invention have the same advantages as the corresponding features of the method of example embodiments of the present invention.

Example embodiments of the present invention are explained in greater detail below with reference to the appended Figures.

### BRIEF DESCRIPTION OF THE DRAWINGS

FIG. 1 is a schematic view of a hybrid vehicle in which a device for determining a charge/aging state of an energy store is provided.

FIG. 2 is a graphic representation of the voltage deviation between the open terminal voltage and the open terminal voltage in the quiescent state, against time.

FIG. 3 is a graphic representation of the voltage deviation between the open terminal voltage and the open terminal voltage in the quiescent state, as well as the corresponding charge state, against time in each case.

FIG. 4 is a graph of a charge state of a capacitor store plotted against time.

### DETAILED DESCRIPTION

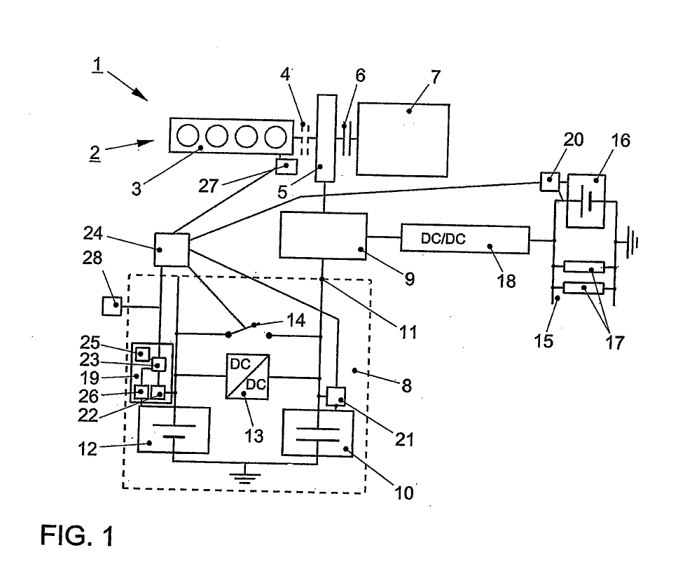

FIG. 1 is a schematic view of a vehicle 1 having a hybrid drive system 2. Hybrid drive system 2 includes a combustion engine 3, which is connected to an electromachine 5 via an optional clutch 4. Instead of optional clutch 4, a belt drive, a rigid connection or a transmission may be provided as well. Electromachine 5 is connected to driven wheels of vehicle 1 with the aid of a vehicle clutch 6 and a vehicle transmission 7. Via power electronics 9, a hybrid energy store 8 is connected to electromachine 5. Hybrid energy store 8 includes a capacitor store 10, which is directly connected to a connection 11 of hybrid energy store 8. In addition, hybrid energy store 8 includes a battery 12, which is connected in parallel to capacitor store 10 via a DC/DC transducer 13 and a switch 14. Battery 12 may be arranged as a battery module. If switch 14 is in a closed position, then a direct electrical connection is established between connection 11 of hybrid energy store 8 and battery 12. If switch 14 is in an open position, an exchange of energy between capacitor store 10 and battery 12 may take place only via DC/DC transducer 13.

In addition to hybrid energy store 8, vehicle 1 has a vehicle electrical system 15, which includes an electrical energy store arranged as a buffer battery 16. Buffer battery 16 of vehicle electrical system 15 normally is a 12V battery, which provides load circuits 17 with energy if vehicle energy system 15 is not supplied with energy via an additional DC/DC transducer 18. Additional DC/DC transducer 18 is connected to power electronics 9. If electromachine 5 is operated in a generator-driven manner, then the supply of vehicle electrical system 5 may be implemented via the additional DC/DC transducer 18. Otherwise, the electrical energy may be supplied to vehicle electrical system 15 from hybrid energy store 8 via additional DC/DC transducer 18.

During operation, capacitor store 10 may be utilized to store and distribute electrical energy from hybrid energy store 8. Prior to starting hybrid drive system 2, a quantity of energy sufficient to operate electromachine 5 in an engine-driven manner and thereby to start combustion engine 3 may be stored in capacitor store 10. If the quantity of energy stored in capacitor store 10 is insufficient for this purpose, then energy is able to be transferred from battery 12 into capacitor store 10 via DC/DC transducer 13 prior to the start. As an alternative, switch 14 may be closed during the start if a voltage of capacitor store 10 has dropped to a nominal battery voltage of battery 12. In this case, a portion of the energy required to start combustion engine 3 will be withdrawn from battery 12.

If electromachine 5 is operated in a generator-actuated manner, such as during a braking operation, then electrical energy is fed into hybrid energy store 8 via the power electronics. To protect battery 12, capacitor store 10 is usually operated at a voltage above a nominal voltage level of battery 12. Switch 14 will be in its open position so that electrical energy is stored in capacitor store 10. If battery 12 is not fully charged, energy is able to be transmitted into battery 12 from capacitor store 10 via DC/DC transducer 13.

At low combustion engine speeds, the electromachine may additionally be used as a propulsion device. Electromachine 5 is operated in a motor-actuated manner for this purpose. The simultaneous motor-actuated operation of combustion engine 3 and electromachine 5 is referred to as boost operation. The high torques of hybrid drive system 2 released in the process are usually required only for brief acceleration phases, so that the energy stored in capacitor store 10 will suffice as a rule. Only during heavy acceleration phases of longer duration or during longer lasting uphill driving will the energy stored in capacitor store 10 not be sufficient, so that switch 14 is closed as soon as the voltage at the capacitor store has dropped to the nominal voltage level of battery 12. Electrical energy from battery 12 will be used in addition in order to maintain the boost operation of hybrid drive system 2. The energy drained in the process lowers a charge state of the battery (SOC). If the combustion engine is subsequently operated at higher combustion engine speeds, an additional engine-actuated drive of electromachine 5 is not helpful because of the torque characteristic of electromachines. In this higher combustion engine speed range, there is thus no need to store energy in capacitor store 10 for an electromotoric propulsion operation. Instead, it makes sense to discharge capacitor store 10 to such a degree that it has storage capacity for storing recuperation energy from braking operations.

As can be gathered from the above description of the method of functioning of a hybrid drive arrangement, excellent knowledge of the charge and/or the aging state of the individual energy stores, i.e., battery 12, capacitor store 10, and buffer battery 16, is important.

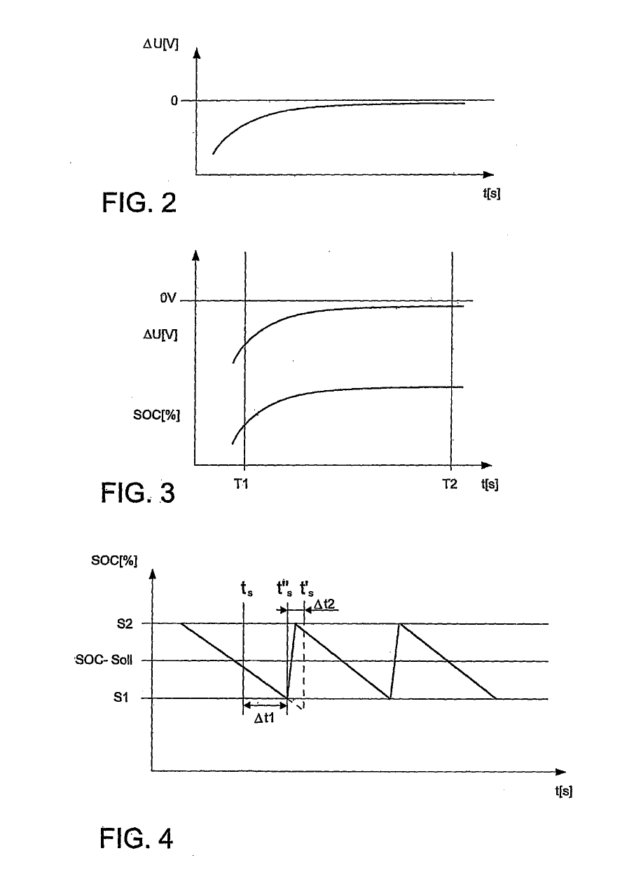

FIG. 2 shows the general relationship of the measured open terminal voltage of a battery relative to the open-circuit voltage in a load-free state following a charge withdrawal from the battery. Plotted is voltage deviation ΔU between the open terminal voltage and the open terminal voltage in the quiescent state (open-circuit voltage) against time. It can be seen that the deviation between the open terminal voltage and the open-circuit voltage decreases over time.

In order to determine the charge and/or aging state of the individual energy stores in the hybrid vehicle according to FIG. 1, devices 19, 20, 21 for determining the charge/aging state of the particular energy stores are provided. In the following text, device 19 for determining the charge/aging state of battery 12 will be described as an example.

Device 19 for determining the charge/aging state includes a voltage-measuring sensor 22 and a control unit 23. When battery 12 reaches a load-free state, control unit 23 initiates a measurement of an open terminal voltage of battery 12 by voltage-measuring sensor 22. The occurrence of a load-free state may be indicated to the control unit via a signal of an energy-management controller 24, for instance. On the basis of the measured open terminal voltage and with the aid of a prediction model, control unit 23 determines a future instant at which battery 12 can be expected to be in a quiescent state according to the prediction model. The prediction model may include mathematically evaluable equations and/or reference tables, which are stored in a memory 25. The prediction model is able to be arranged in software or in hardware as well. The prediction model may take additional physical variables into account, such as a temperature of battery 12 measured with the aid of a temperature sensor 26, a temperature of combustion engine 3 measured with the aid of an engine-temperature sensor 27, as well as an ambient temperature, for example, which is supplied by other vehicle components and is represented by a box 28. In addition, the other vehicle components may transmit to device 19 additional information concerning, for instance, a driving behavior, time of day and/or season information, for determining the charge and/or aging state. At the future instant, ascertained with the aid of the prediction model, voltage-measurement sensor 22 determines at least one additional open terminal voltage at the request of control unit 23. It is used to determine the charge state of battery 12 with the aid of a previously known relation, which is stored, for example, in memory 25 in the form of tables, or which is able to be calculated with the aid of a mathematical equation. The prediction model specifies the future instant such that battery 12 is expected to be in a state of rest, so that the open terminal voltage measured at the future instant allows a precise determination of the charge and aging state. Devices 20, 21 for determining the charge and/or aging state are merely symbolized by a box, but they have the same or a similar configuration as device 19 for determining the aging and/or charge state.

In FIG. 3, the relationship between the deviation of the open terminal voltage and the open-circuit voltage and the charge state, determined accordingly, has been plotted graphically against time. At instant T1, the open terminal voltage is measured. The prediction model predicts that an approximate quiescent state of the energy store is reached at instant T2. Using the open terminal voltage measured at instant T2, the charge state (SOC) will be determined. This charge state conforms much more closely to the actual charge state of the energy store in the quiescent state than the charge state that is determined at instant T1 based on the measured open terminal voltage.

With the aid of FIG. 4, it will be described in which manner the prediction model may be adapted if the measurement of the open terminal voltage at the future instant deviates from an open terminal voltage predicted for this future instant based on the prediction model. In FIG. 4, the charge state of a capacitor store, such as capacitor store 10 according to FIG. 1, for instance, has been plotted against time. The charge state of a load-free capacitor store is substantially determined by a self-discharge characteristic. In order to always have available in the capacitor store a specifiable energy quantity that is sufficient, for example, to drive electromachine 5 according to FIG. 1 in an engine-actuated manner in order to be able to start combustion engine 3 according to FIG. 1, it is provided that the capacitor store always has a desired setpoint charge state (SOC-setpoint). To prevent continuous recharging of the capacitor store by a weak charge current which compensates for the self-discharge, it may be provided to charge the capacitor store to a maximum setpoint charge state S2 whose charge state is greater than the targeted setpoint charge state SOC-setpoint. Following the charging, the capacitor store reaches a load-free state, and the open terminal voltage is determined. With the aid of a prediction model, which substantially encompasses the self-discharge characteristic of the capacitor store, a future instant tS is specified at which another open terminal voltage measurement is carried out at the capacitor store in order to ascertain its charge state. If it is determined by the measurement that the charge state of the capacitor store has not yet dropped to a predefined minimum setpoint charge state S1, the prediction model is adapted such that the future instant is extended by a time period Δt1. Time period Δt1 corresponds to the particular time that still needs to elapse before the charge state of the capacitor store has dropped to minimum setpoint charge state S1. On the other hand, if future instant t_{S}′ is specified with the aid of the prediction model in order to determine the further open terminal voltage, and if it is determined based on the further open terminal voltage that the charge state of the capacitor store has already dropped below minimum setpoint charge state S1, the prediction model is modified such that the future instant is specified to occur earlier by a time interval Δt2, so that a determination of future instant t_{S}″ with the aid of the prediction model becomes optimal in the future, i.e., is specified precisely to the instant at which the charge state of the capacitor store has dropped to minimum setpoint charge state S1. If, based on the measurement of the open terminal voltage of the capacitor store, it is determined that the charge state corresponds to minimum setpoint charge state S1 or lies below it, then the capacitor store is once again charged to maximum setpoint charge state S2. Subsequently another measurement of the open terminal voltage takes place for checking purposes, in order to ascertain that maximum setpoint charge state S2 has been reached. Using the prediction model, a future instant will then again be specified at which the open terminal voltage of the capacitor store is measured once more in order to ascertain whether the charge state of the capacitor store has dropped to minimum setpoint charge state S1.

1-16. (canceled)

17. A method for determining a charge/aging state of an energy store based on a measurement of an open terminal voltage of the energy store in a load-free state, comprising:
measuring a first open terminal voltage at a first instant;
defining a future instant for at least one further measurement of the open terminal voltage based on the measured first open terminal voltage and in accordance with a prediction model;
measuring at least one additional open terminal voltage at the future instant; and
determining the charge/aging state of the energy store based on the at least one additional open terminal voltage.

18. The method according to claim 17, wherein the future instant is defined in the defining step to predict a quiescent state of the energy store for the future instant based on the prediction model.

19. The method according to claim 18, wherein the quiescent state is determined based on the open terminal voltage being substantially constant over time.

20. The method according to claim 17, further comprising measuring additional open terminal voltages at the future instant.

21. The method according to claim 17, further comprising:
comparing the at least one additional open terminal voltage to an open terminal voltage predicted on the basis of the prediction model at the future instant, and
adapting the prediction model if the at least one additional open terminal voltage deviates from a predicted open terminal voltage by more than a specified tolerance.

22. The method according to claim 17, further comprising:
at least one of (a) measuring and (b) recording at least one of (a) additional physical and (b) additional statistical variables; and
taking into account the at least one of (a) the additional physical and (b) the additional statistical variable in the prediction model.

23. The method according to claim 22, wherein at least one of (a) the physical variables include at least one of (i) an energy-store temperature, (ii) an ambient temperature, (iii) a charge/discharge current, and (iv) a charge/discharge output prior to an occurrence of the load-free state, and (b) the statistical variables include at least one of (i) a time of day, (ii) an indicated season, and (iii) information regarding a driving behavior.

24. A device for determining a charge/aging state of an energy store, comprising:
a voltage-measurement sensor configured to measure an open terminal voltage of the energy store in a load-free state; and
a control unit configured to determine the charge/aging state based on the open terminal voltage of the energy store in the load-free state;
wherein the control unit is configured to initiate, at a first instant, a measurement of a first open terminal voltage after occurrence of the load-free state of the energy store and, based on the measured first open terminal voltage, the control unit, in accordance with a prediction model, is configured to specify a future instant for at least one additional measurement of the open terminal voltage, at least one additional open terminal voltage measurable at the future instant, the charge/aging state of the energy store determinable based on the at least one additional open terminal voltage.

25. The device according to claim 24, wherein the control unit is configured to specify the future instant to predict a quiescent state of the energy store for the future instant based on the prediction model.

26. The device according to claim 25, wherein the quiescent state corresponds to the open terminal voltage being substantially constant over time.

27. The device according to claim 24, wherein additional open terminal voltages are measurable at the future instant to confirm a reliability of the at least one additional open terminal voltage measured at the future instant.

28. The device according to claim 24, wherein the control unit includes an adaptation unit configured to compare the at least one additional open terminal voltage to an open terminal voltage at the future instant predicted based on the prediction model, and configured to adapt the prediction model if the at least one additional open terminal voltage deviates from a predicted open terminal voltage by more than a specified tolerance.

29. The device according to claim 24, wherein at least one of (a) additional physical and (b) additional statistical variables are taken into account in the prediction model.

30. The device according to claim 29, wherein at least one of (a) the physical variables include at least one of (i) an energy store temperature, (ii) an ambient temperature, (iii) a charge/discharge current, and (iv) a charge/discharge output prior to occurrence of the load-free state, and (b) the statistical variables include at least one of (i) a time of day, (ii) an indicated season, and (iii) information regarding a driving behavior.

31. The device according to claim 29, further comprising at least one of (a) at least one additional sensor configured to measure the physical variables and (b) at least one detection device configured to detect the statistical variables.

32. The device according to claim 31, wherein the sensor includes at least one temperature sensor.

33. The device according to claim 24, wherein the prediction model includes mathematically evaluable equations.

34. The device according to claim 24, wherein the prediction model includes reference tables stored in a memory.
